(19) United States
(12) Patent Application Publication
(10) Pub. No.: US 2022/0360041 A1
(43) Pub. Date: Nov. 10, 2022

(54) OPTICAL SEMICONDUCTOR DEVICE AND INTEGRATED SEMICONDUCTOR LASER DEVICE

(71) Applicant: FURUKAWA ELECTRIC CO., LTD., Tokyo (JP)

(72) Inventors: Masahiro YOSHIDA, Tokyo (JP); Toshihito SUZUKI, Tokyo (JP)

(73) Assignee: FURUKAWA ELECTRIC CO., LTD., Tokyo (JP)

(21) Appl. No.: 17/871,019

(22) Filed: Jul. 22, 2022

Related U.S. Application Data
(63) Continuation of application No. PCT/JP2021/002496, filed on Jan. 25, 2021.

(30) Foreign Application Priority Data
Jan. 29, 2020 (JP) 2020-012095

(51) Int. Cl. H01S 5/042; H01S 5/227; H01S 5/024; H01S 5/026

(52) U.S. Cl. CPC H01S 5/042; H01S 5/227; H01S 5/02461; H01S 5/026

(57) ABSTRACT

An optical semiconductor device includes: a base including a base surface; a mesa protruding from the base surface in a first direction intersecting the base surface and extending along the base surface; an optical waveguide layer provided inside the mesa or provided inside the base so as to have a region at least overlapping with the mesa in the first direction; an electric resistance layer including a first region provided on the mesa, and a first extending portion extending from the first region in a direction intersecting an extending direction of the mesa; and a wiring layer including a second region electrically connected to the electric resistance layer and configured to partially cover the first region, and a second extending portion configured to at least partially cover the first extending portion and extending from the second region in a direction intersecting the extending direction of the mesa.

This application is a continuation of International Application No. PCT/JP2021/002496, filed on Jan. 25, 2021 which claims the benefit of priority of the prior Japanese Patent Application No. 2020-012095, filed on Jan. 29, 2020, the entire contents of which are incorporated herein by reference.

### BACKGROUND

The present disclosure relates to an optical semiconductor device and an integrated semiconductor laser device.

In the related art, there is a known optical semiconductor device that includes, on a mesa, an electric resistance layer that functions as a heater and a wiring layer that supplies electricity to the electric resistance layer (Japanese Laid-open Patent Publication No. 2017-163081).

### SUMMARY

With the configuration described in Japanese Laid-open Patent Publication No. 2017-163081, in some cases, a burr is produced at an edge of the electric resistance layer. In such a case, when the wiring layer is formed across the edge, the wiring layer is not formed in an expected shape on the edge due to the burr, and, in addition, electric resistance in the wiring layer may possibly increase.

There is a need for a wiring layer that is less affected by a burr produced at an edge of an electric resistance layer in an optical semiconductor device that includes, for example, on a mesa, an electric resistance layer and a wiring layer.

According to one aspect of the present disclosure, there is provided an optical semiconductor device including: a base including a base surface; a mesa protruding from the base surface in a first direction intersecting the base surface and extending along the base surface; an optical waveguide layer provided inside the mesa or provided inside the base so as to have a region at least overlapping with the mesa in the first direction; an electric resistance layer including a first region provided on the mesa, and a first extending portion extending from the first region in a direction intersecting an extending direction of the mesa; and a wiring layer including a second region electrically connected to the electric resistance layer and configured to partially cover the first region, and a second extending portion configured to at least partially cover the first extending portion, the second extending portion extending from the second region in a direction intersecting the extending direction of the mesa, wherein a connecting region electrically connected to wiring is provided at a position included in the second extending portion, the position overlapping with the first extending portion.

According to another aspect of the present disclosure, there is provided an optical semiconductor device including: a base including a base surface; a mesa protruding from the base surface in a first direction intersecting the base surface and extending along the base surface; an optical waveguide layer provided inside the mesa or provided inside the base so as to have a region at least overlapping with the mesa in the first direction; an electric resistance layer including a first region provided on the mesa, and a first extending portion extending from the first region in a direction intersecting an extending direction of the mesa; and a wiring layer including a second region electrically connected to the electric resistance layer and configured to partially cover the first region, and a second extending portion configured to at least partially cover the first extending portion, the second extending portion extending from the second region in a direction intersecting the extending direction of the mesa, wherein the second extending portion includes a third region having a width larger than a width of the first extending portion, the third region overlapping with the first extending portion, and a connecting region electrically connected to wiring at a position away from the second region.

### BRIEF DESCRIPTION OF THE DRAWINGS

FIG. 1 is an exemplary and schematic perspective view illustrating an optical semiconductor device including a part of a cross-sectional surface according to a first embodiment;

FIG. 2 is a cross-sectional view taken along line II-II illustrated in FIG. 1;

FIG. 3 is an exemplary and schematic plan view illustrating a state in which a wiring layer is removed from a part of the optical semiconductor device according to the first embodiment;

FIG. 4 is an exemplary and schematic plan view illustrating a part of the optical semiconductor device according to the first embodiment;

FIG. 5 is a cross-sectional view illustrating an optical semiconductor device according to a first modification of an embodiment when viewed from a position equivalent to that illustrated in FIG. 2;

FIG. 6 is a cross-sectional view illustrating an optical semiconductor device according to a second modification of an embodiment when viewed from a position equivalent to that illustrated in FIG. 2;

FIG. 7 is an exemplary and schematic perspective view illustrating an optical semiconductor device including a part of a cross-sectional surface according to a third modification of an embodiment;

FIG. 8 is an exemplary and schematic perspective view including a part of a cross-sectional surface of an optical semiconductor device according to a fourth modification of an embodiment;

FIG. 9 is a cross-sectional view taken along line IX-IX illustrated in FIG. 8;

FIG. 10 is an exemplary and schematic perspective view including a part of a cross-sectional surface of an optical semiconductor device according to a fifth modification of an embodiment;

FIG. 11 is an exemplary and schematic perspective view including a part of a cross-sectional surface of an optical semiconductor device according to a sixth modification of an embodiment;

FIG. 12 is an exemplary and schematic perspective view including a part of a cross-sectional surface of an optical semiconductor device according to a seventh modification of an embodiment;

FIG. 13 is a plan view illustrating an optical semiconductor device according to an eighth modification of an embodiment when viewed from a position equivalent to that illustrated in FIG. 4;

FIG. 14 is a plan view illustrating an optical semiconductor device according to a ninth modification of an embodiment when viewed from a position equivalent to that illustrated in FIG. 4;

FIG. 15 is a plan view illustrating an optical semiconductor device according to a tenth modification of an embodiment when viewed from a position equivalent to that illustrated in FIG. 4;

FIG. 16 is a perspective view illustrating an integrated semiconductor laser device including the optical semiconductor device according to a second embodiment;

FIG. 17 is an exemplary and schematic perspective view illustrating the optical semiconductor device including a part of a cross-sectional surface according to the second embodiment applied to DBR; and

FIG. 18 is an exemplary and schematic perspective view illustrating the optical semiconductor device including a part of a cross-sectional surface according to the second embodiment applied to a ring resonator.

### DETAILED DESCRIPTION

Exemplary embodiments and modifications of the present disclosure will be disclosed below. Configurations of the embodiments and the modifications described below, and operations and results (effects) achieved by the configurations are mere examples. The present disclosure may be implemented by configurations other than the configurations disclosed in the embodiments and the modifications below. Furthermore, according to the present disclosure, it is possible to obtain at least one of various effects (including derivative effects) that are achieved by the configurations.

The embodiments and the modifications described below have the same configurations. Therefore, according to the configurations of each of the embodiments and the modifications, it is possible to achieve the same operations and effects based on the same configurations. Furthermore, in the following, the same configurations are denoted by the same reference symbols, and, in some cases, repeated explanation may be omitted.

In the present specification, ordinal numbers are assigned, for the sake of convenience, to distinguish between components, parts, and the like, and do not indicate priorities or order.

Furthermore, in each of the drawings, an X-direction is indicated by an arrow X, a Y-direction is indicated by an arrow Y, and a Z-direction is indicated by an arrow Z. The X-direction, the Y-direction, and the Z-direction intersects with each other and are perpendicular with each other as well as intersect with each other. In addition, the X-direction may also be referred to as a longitudinal direction or an extending direction, the Y-direction may also be referred to as a shorter direction, a width direction, or a thickness direction, the Z-direction may also be referred to as a height direction or a projecting direction.

### First Embodiment

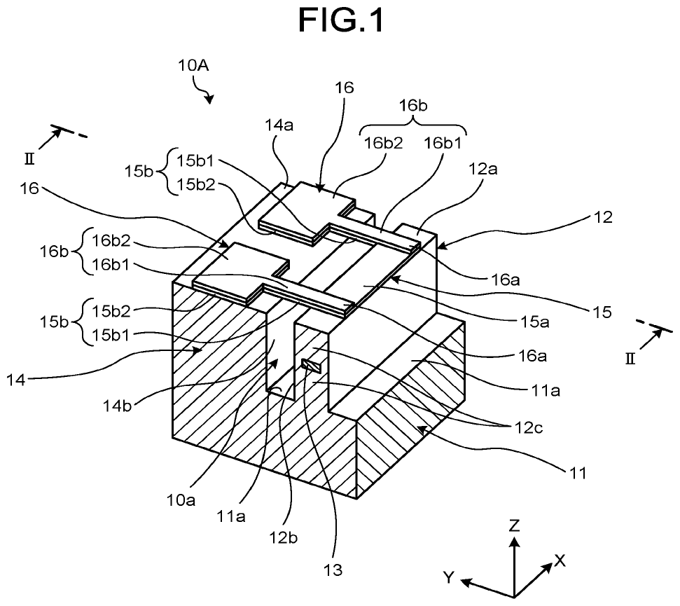

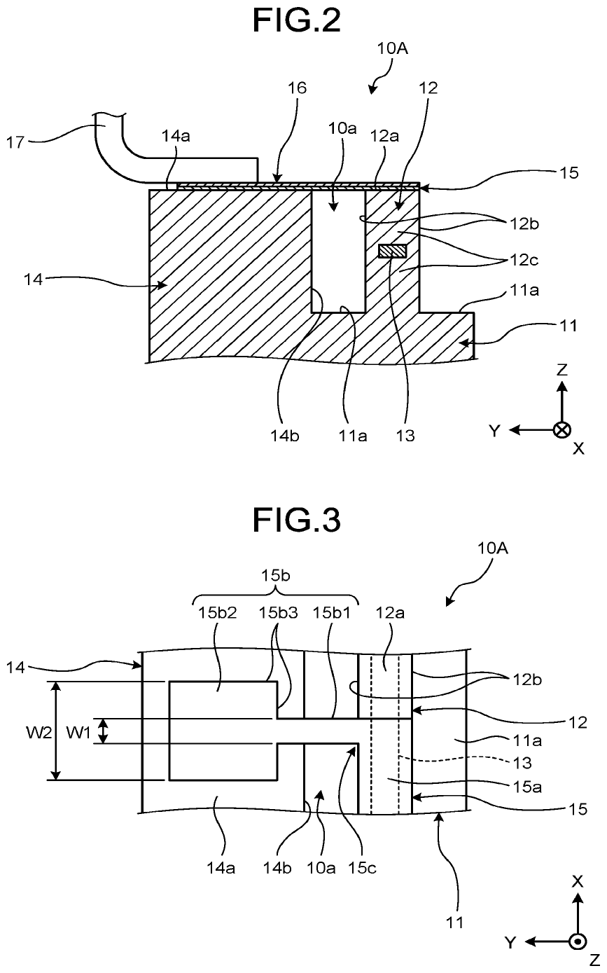

FIG. 1 is a perspective view illustrating an optical semiconductor device 10A including a part of a cross-sectional surface according to the present embodiment. FIG. 1 illustrates, together with an obliquely viewed shape, a cross-sectional surface perpendicular to the X-direction and a cross-sectional surface perpendicular to the Y-direction. Furthermore, FIG. 2 is a cross-sectional view taken along line II-II illustrated in FIG. 1.

As illustrated in FIGS. 1 and 2, the optical semiconductor device 10A includes a substrate 11, a mesa 12, an optical waveguide layer 13, a laminated portion 14, an electric resistance layer 15, and wiring layers 16.

The substrate 11 is a semiconductor substrate. The substrate 11 extends in a direction intersecting the Z-direction. In the present embodiment, the substrate 11 extends in the X-direction and the Y-direction and is perpendicular to the Z-direction. Furthermore, the substrate 11 includes a base surface 11a. The base surface 11a has a flat shape and extends in a direction intersecting the Z-direction. In the present embodiment, the base surface 11a extends in the X-direction and the Y-direction and is perpendicular to the Z-direction. The substrate 11 is an example of a base. The base surface 11a may also be referred to as a front surface.

The substrate 11 may be made of, for example, n-type indium phosphide (InP).

The mesa 12 protrudes in the Z-direction from the base surface 11a of the substrate 11 with a substantially certain width in the Y-direction. Furthermore, the mesa 12 extends in the X-direction with a substantially certain height in the Z-direction. In other words, the mesa 12 has a shape, such as a wall shape, upwardly protruding from the base surface 11a. In addition, the mesa 12 may extend along the base surface 11a while being bent. Furthermore, the width of the mesa 12 may be changed along the Z-direction, that is, the height direction, or may be changed along the X-direction, that is, the extending direction. The Z-direction is an example of a first direction.

The mesa 12 includes a top surface 12a and two side surfaces 12b.

The top surface 12a extends in a direction intersecting the Z-direction. In the present embodiment, the top surface 12a extends in the X-direction and the Y-direction, and is perpendicular to the Z-direction. The top surface 12a is substantially parallel to the base surface 11a. Furthermore, the top surface 12a extends in the X-direction with a substantially certain width in the Y-direction. Furthermore, the top surface 12a may extend substantially parallel to the base surface 11a while being bent. In addition, the width of the top surface 12a may be changed along the extending direction of the mesa 12.

The side surface 12b extends in the Z-direction along the Z-direction. Furthermore, the side surface 12b extends in the X-direction with a substantially certain width in the Z-direction. In addition, the side surface 12b may extend along the base surface 11a while being bent.

The optical waveguide layer 13 is provided inside the mesa 12. The optical waveguide layer 13 is disposed at a position between the root of the mesa 12 and the top surface 12a. The optical waveguide layer 13 extends in the X-direction with a substantially certain width in the Y-direction and with a substantially certain height in the Z-direction. In addition, the optical waveguide layer 13 may extend substantially parallel to the base surface 11a while being bent together with the mesa 12.

In the present embodiment, the width of the optical waveguide layer 13 is smaller than the width of the mesa 12, and the circumference of the optical waveguide layer 13 is covered by the mesa 12 (a cladding layer 12c).

The laminated portion 14 upwardly protrudes in the Z-direction from the substrate 11. The laminated portion 14 includes a top surface 14a and a side surface 14b.

The top surface 14a extends in a direction intersecting the Z-direction. In the present embodiment, the top surface 14a extends in the X-direction and the Y-direction, and is perpendicular to the Z-direction. The top surface 14a is substantially parallel to the base surface 11a.

The side surface 14b extends in the Z-direction along the Z-direction. Furthermore, the side surface 14b extend in the X-direction with a substantially certain width in the Z-direction. In addition, the side surface 14b may extend along the base surface 11a while being bent.

The optical semiconductor device 10A is provided with a trench 10a that is adjacent to the mesa 12 and the laminated portion 14.

The mesa 12 including the optical waveguide layer 13 and the laminated portion 14 may be made of a known semiconductor manufacturing process. The region excluding the optical waveguide layer 13 included in the mesa 12 functions as the cladding layer 12c with respect to the optical waveguide layer 13. The cladding layer 12c may be made of a material having a lower refractive index than that of the material of the optical waveguide layer 13. For example, if the wavelength of light guided by the optical waveguide layer 13 is 1.55 μm, the cladding layer 12c may be made of InP, whereas the optical waveguide layer 13 may be made of InGaAsP. Furthermore, the materials of the cladding layer 12c and the optical waveguide layer 13 are not limited to these, but may appropriately be set in accordance with the wavelength of the light that is guided by the optical waveguide layer 13. In addition, the laminated portion 14 may be made of a semiconductor material.

The base surface 11a of the substrate 11, the top surface 12a and the side surface 12b of the mesa 12, and the top surface 14a and the side surfaces 14b of the laminated portion 14 may be covered by a dielectric layer (not illustrated). In this case, the dielectric layer is formed on each of the surfaces with a substantially thickness. The dielectric layer has insulation properties. The dielectric layer may be made of, for example, silicon nitride (SiNₓ) or silicon dioxide (SiO₂).

FIG. 3 is a plan view illustrating a state in which the wiring layer 16 is removed from a part of the optical semiconductor device 10A. As illustrated in FIGS. 1 to 3, in the present embodiment, the electric resistance layer 15 is provided from the top surface 12a of the mesa 12 toward the top surface 14a of the laminated portion 14 so as to be laid across the trench 10a.

The electric resistance layer 15 may be made of a material, such as an alloy made of, for example, nickel (Ni) and chromium (Cr) as a main component, that generates heat caused by energization. The electric resistance layer 15 generates heat due to electrical power that is supplied from the two wiring layers 16 that are separated with each other in the extending direction of the mesa 12 (the X-direction in the present embodiment). In the electric resistance layer 15, an electric current flows along the extending direction of the mesa 12. The electric resistance layer 15 may be called as a heater.

As illustrated in FIGS. 1 and 3, the electric resistance layer 15 includes a first region 15a that is provided on the mesa 12 and a first extending portion 15b that extends from the first region 15a toward the laminated portion 14.

The first region 15a extends in the extending direction of the mesa 12 on the top surface 12a of the mesa 12, that is, in the X-direction in the present embodiment. The first region 15a has a square shape and also has a plate shape. Furthermore, the first region 15a has a belt shape extending along the top surface 12a of the mesa 12.

The first extending portion 15b extends from the end portion of the first region 15a in the extending direction in a direction intersecting the extending direction of the mesa 12. In the present embodiment, the top surface 12a of the mesa 12 is flush with the top surface 14a of the laminated portion 14, and the first extending portion 15b extends from the first region 15a in the width direction of the mesa 12, that is, in the Y-direction in the present embodiment.

As illustrated in FIG. 3, the first extending portion 15b includes a narrow width region 15b1 and a wide width region 15b2. The narrow width region 15b1 has a square shape and also has a plate shape, and extends from the first region 15a with a substantially certain width. The wide width region 15b2 is located at an end portion that is located on the opposite side of the first region 15a from which the narrow width region 15b1 extends, and has a width larger than that of the narrow width region 15b1. The width of the narrow width region 15b1 is W1, whereas the width of the wide width region 15b2 is W2 (>W1). In the present embodiment, the width W1 of the narrow width region 15b1 is substantially constant, so that the width of the first extending portion 15b in a boundary region 15c between the first extending portion 15b and the first region 15a is also W1. In other words, the width W2 of the wide width region 15b2 is larger than the width W1 of the boundary region 15c. The wide width region 15b2 has a square shape and also has a plate shape. As an example, in the present embodiment, the narrow width region 15b1 has a rectangular shape, whereas the wide width region 15b2 has a square shape.

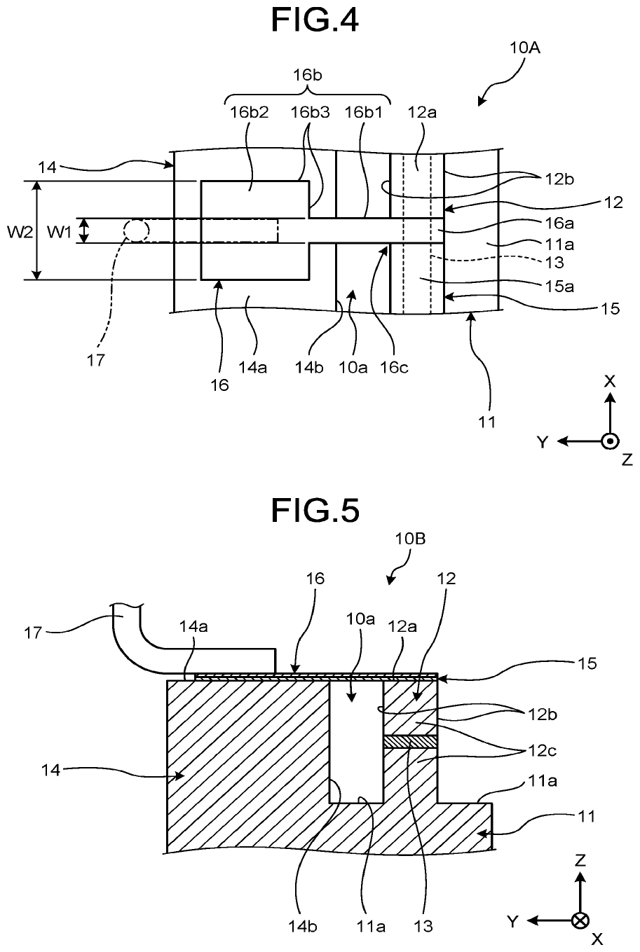

FIG. 4 is a plan view illustrating a part of the optical semiconductor device 10A. As illustrated in FIGS. 1, 2, and 4, in the present embodiment, the wiring layer 16 is provided from the first region 15a of the electric resistance layer 15 toward the wide width region 15b2 of the first extending portion 15b across the trench 10a. The wiring layer 16 is adjacent on a side opposite to a side on which the mesa 12 and the laminated portion 14 are disposed with respect to the electric resistance layer 15. The wiring layer 16 overlaps with the electric resistance layer 15 in the Z-direction and extends along the electric resistance layer 15.

The wiring layer 16 may be formed of a material made of, for example, titanium (Ti), platinum (Pt), or gold (Au), that has conductive properties. The wiring layer 16 acts as a path that supplies electrical power to the electric resistance layer 15. The electric resistivity of the electric resistance layer 15 is larger than the electric resistivity of the wiring layer 16.

As illustrated in FIGS. 1 and 4, the wiring layer 16 includes a second region 16a that is provided on the mesa 12 and a second extending portion 16b that extends from the second region 16a toward the laminated portion 14.

As is clear by referring to FIGS. 1 and 2 and comparing FIG. 3 to FIG. 4, the second region 16a partially covers the end portion of the first region 15a included in the electric resistance layer 15. Furthermore, the second extending portion 16b has the same shape as that of the first extending portion 15b included in the electric resistance layer 15 when viewed from the Z-direction, and overlaps with the first extending portion 15b in the Z-direction.

The second region 16a has a square shape and also has a plate shape.

The second extending portion 16b extends from the second region 16a in a direction intersecting the extending direction of the mesa 12. In the present embodiment, the second extending portion 16b extends from the second region 16a in the width direction of the mesa 12, that is, the Y-direction in the present embodiment.

As illustrated in FIG. 4, the second extending portion 16b includes a narrow width region 16b1 and a wide width region 16b2. The narrow width region 16b1 has a square shape and also has a plate shape and extends from the second region 16a with a substantially certain width. The wide width region 16b2 is located at an end portion that is located on the opposite side of the second region 16a from which the narrow width region 16b1 extends, and has a width larger than that of the narrow width region 16b1. The wide width region 16b2 is located away from the second region 16a. The width of the narrow width region 16b1 is W1, whereas the width of the wide width region 16b2 is W2 (>W1). In the present embodiment, the width W1 of the narrow width region 16b1 is substantially constant, so that the width of the second extending portion 16b in a boundary region 16c between the second extending portion 16b and the second region 16a is also W1. In other words, the width W2 of the wide width region 16b2 is larger than the width W1 of the boundary region 16c. The wide width region 16b2 has a square shape and also has a plate shape. As an example, in the present embodiment, the narrow width region 16b1 has a rectangular shape, whereas the wide width region 16b2 has a square shape.

In the present embodiment, the wide width region 16b2 overlaps with the wide width region 15b2. Then, wiring 17 is bonded by using soldering, welding, or the like on the opposite side of the wide width region 15b2 of the wide width region 16b2 and is electrically connected. In other words, the wide width region 16b2 is an example of a connecting region.

Furthermore, in the present embodiment, an edge 15b3 of the first extending portion 15b included in the electric resistance layer 15 overlaps with an edge 16b3 of the second extending portion 16b in the wiring layer 16 in the Z-direction. As a result, the wiring layer 16 is not laid across the edge of the electric resistance layer 15 in a portion from the second region 16a that partially covers the first region 15a included in the electric resistance layer 15 to the wide width region 16b2 that is electrically connected to the wiring 17. The edge 15b3 is an example of the first edge, whereas the edge 16b3 is an example of the second edge.

As described above, in the present embodiment, the electric resistance layer 15 includes the first region 15a that is provided on the mesa 12, and the first extending portion 15b that extends from the first region 15a in a direction intersecting the extending direction of the mesa 12. Furthermore, the wiring layer 16 includes the second region 16a that is electrically connected to the electric resistance layer 15 and that partially covers the first region 15a, and the second extending portion 16b that at least partially covers the first extending portion 15b and that extends from the second region 16a in a direction intersecting with the extending direction of the mesa 12. Then, the wide width region 16b2 (connecting region) that overlaps with the wide width region 15b2, that is, a position that is included in the second extending portion 16b and that overlaps with the first extending portion 15b is electrically connected to the wiring 17.

With the configuration described above, in a portion from the second region 16a to the wide width region 16b2 that is electrically connected to the wiring 17, the wiring layer 16 is not laid across the edge of the electric resistance layer 15. Thus, with this configuration, for example, it is possible to avoid an increase in electric resistance in the wiring layer 16 caused by a burr produced in the edge of the electric resistance layer 15 or breaking of the wiring layer 16, and, in addition, it is possible to more efficiently supply electrical power to the electric resistance layer 15 via the wiring 17 and the wiring layer 16.

Furthermore, in the present embodiment, the edge 15b3 (the first edge) of the first extending portion 15b overlaps with the edge 16b3 (the second edge) of the second extending portion 16b.

With this configuration, for example, an advantage is provided in that a mask pattern that is used at the time of manufacturing is able to be shared by the first extending portion 15b and the second extending portion 16b.

### [b] First Modification

FIG. 5 is a cross-sectional view of an optical semiconductor device 10B according to the modification when viewed from a position equivalent to that illustrated in FIG. 2. As illustrated in FIG. 5, the optical waveguide layer 13 passes through a portion between the two side surfaces 12b of the mesa 12. The configuration of the optical semiconductor device 10B is the same as that of the optical semiconductor device 10A according to the first embodiment except that the configuration and the arrangement of the optical waveguide layer 13 are different. With this configuration, it is also possible to obtain the same effect as that obtained in the first embodiment described above.

### Second Modification

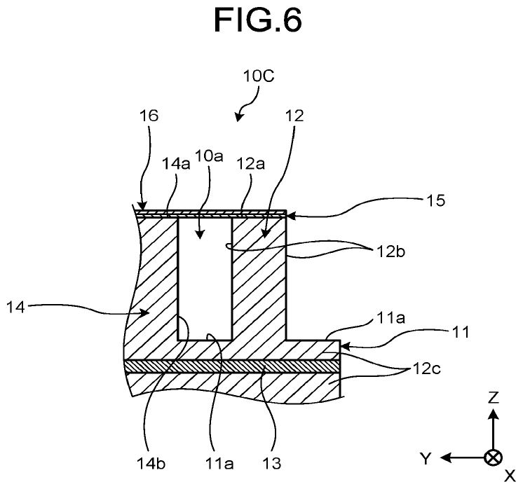

FIG. 6 is a cross-sectional view of an optical semiconductor device 10C according to this modification when viewed from a position equivalent to that illustrated in FIG. 2. As illustrated in FIG. 6, in this modification, the optical semiconductor device 10C has a so-called low mesa structure (ridge structure). The optical waveguide layer 13 is provided inside the substrate 11 that is located at a position away from the mesa 12 in a direction opposite to the Z-direction. The optical waveguide layer 13 has a region that overlaps with the mesa 12 in the Z-direction. Light is guided by being confined, by the mesa 12, inside the area that is located in a direction opposite to the Z-direction with respect to the mesa 12 included in the optical waveguide layer 13. The optical semiconductor device 10C has the same configuration as that of the optical semiconductor device 10A according to the first embodiment described above except that the configuration and the arrangement of the optical waveguide layer 13 are different. With this configuration, it is also possible to obtain the same effect as that obtained in the first embodiment described above.

### Third Modification

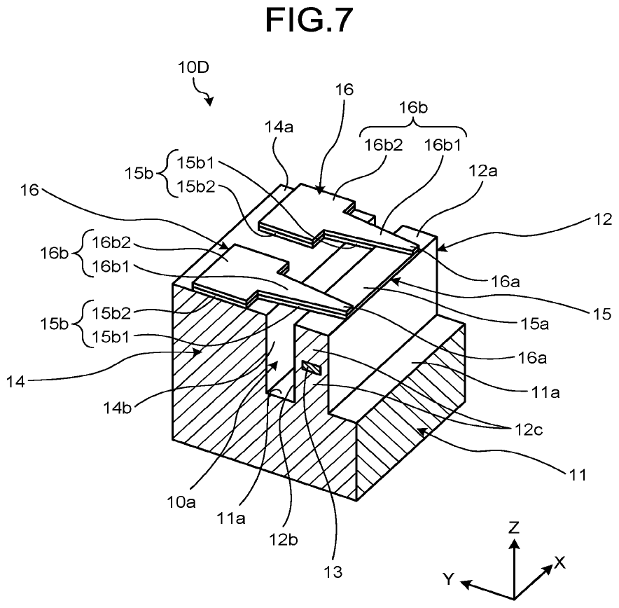

FIG. 7 is a perspective view of an optical semiconductor device 10D according to this modification including a part of a cross-sectional surface. FIG. 7 illustrates, together with an obliquely viewed shape, a cross-sectional surface perpendicular to the X-direction and a cross-sectional surface perpendicular to the Y-direction. As illustrated in FIG. 7, in the optical semiconductor device 10D, the width of the first extending portion 15b included in the electric resistance layer 15 and the width of the second extending portion 16b included in the wiring layer 16 are increased as these portions are away from the mesa 12, the first region 15a, and the second region 16a. With this configuration, it is possible to further increase a cross-sectional area of the second extending portion 16b, and, in addition, it is possible to further reduce electric resistance of the wiring layer 16.

Furthermore, also in this modification, similar to the first embodiment, the second extending portion 16b overlaps with the first extending portion 15b in the Z-direction, and the edge 16b3 of the second extending portion 16b (see FIG. 4) overlaps with the edge 15b3 of the first extending portion 15b (see FIG. 3) in the Z-direction. Furthermore, the wide width region 16b2 (connecting region) that overlaps with the wide width region 15b2, that is, a position that is included in the second extending portion 16b and that overlaps with the first extending portion 15b is electrically connected to the wiring 17. As a result, in a portion from the second region 16a to the wide width region 16b2 that is electrically connected to the wiring 17, the wiring layer 16 is not laid across the edge of the electric resistance layer 15. In this modification, it is also possible to obtain the same effect as that described above in the first embodiment.

### Fourth Modification

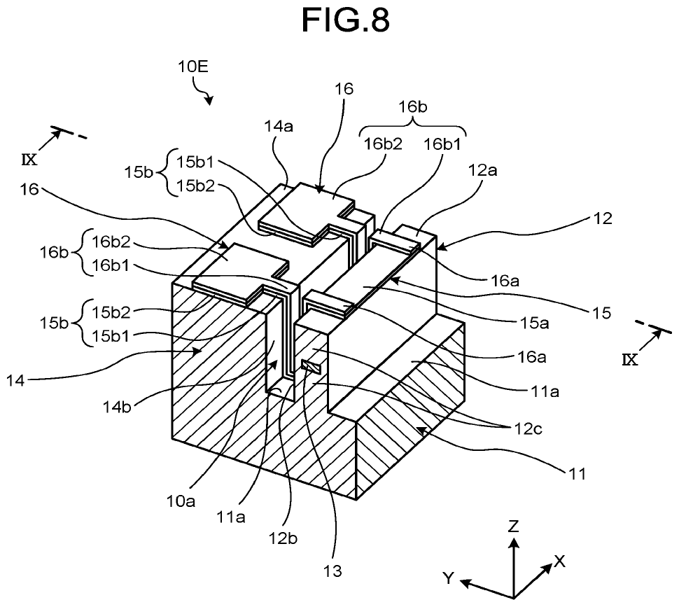

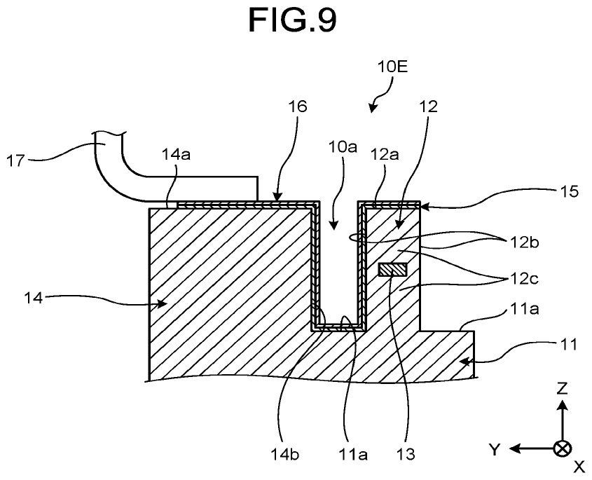

FIG. 8 is a perspective view of an optical semiconductor device 10E according to this modification including a part of a cross-sectional surface. FIG. 8 illustrates, together with an obliquely viewed shape, a cross-sectional surface perpendicular to the X-direction and a cross-sectional surface perpendicular to the Y-direction. Furthermore, FIG. 9 is a cross-sectional view taken along line IX-IX illustrated in FIG. 8.

As illustrated in FIGS. 8 and 9, in this modification, the first extending portion 15b included in the electric resistance layer 15 and the second extending portion 16b included in the wiring layer 16 are not laid across the trench 10a away from the base surface 11a as described in the first embodiment or the like, the first extending portion 15b in the electric resistance layer 15 and the second extending portion 16b in the wiring layer 16 extend along the side surfaces and the bottom surface of the trench 10a, that is, the side surfaces 12b of the mesa 12, the base surface 11a, the side surfaces 14b of the laminated portion 14, and the top surface 14a.

In this modification, the second extending portion 16b overlaps with the first extending portion 15b in the direction that is perpendicular to each of the surfaces parallel to the first extending portion 15b, and the edge 16b3 of the second extending portion 16b (see FIG. 4) overlaps with the edge 15b3 of the first extending portion 15b in the direction that is perpendicular to each of the surfaces parallel to the edge 15b3 of the first extending portion 15b (see FIG. 3). Furthermore, in the wide width region 16b2 (connecting region) that overlaps with the wide width region 15b2, that is, a position that is included in the second extending portion 16b and that overlaps with the first extending portion 15b is electrically connected to the wiring 17. As a result, in a portion from the second region 16a to the wide width region 16b2 that is electrically connected to the wiring 17, the wiring layer 16 is not laid across the edge of the electric resistance layer 15. In this modification, it is also possible to obtain the same effect as that described above in the first embodiment. Furthermore, according to this modification, the first extending portion 15b and the second extending portion 16b extend along the trench 10a without being laid across the trench 10a, it is possible to further increase mechanical strength of each of the first extending portion 15b and the second extending portion 16b, and it is also possible to further simplify a manufacturing process for forming the first extending portion 15b and the second extending portion 16b, which is an advantage.

### Fifth Modification

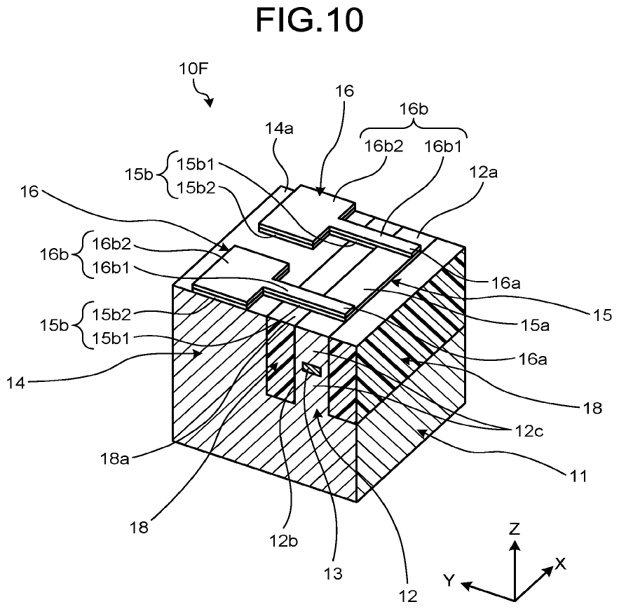

FIG. 10 is a perspective view of an optical semiconductor device 10F according to this modification including a part of a cross-sectional surface. FIG. 10 illustrates, together with an obliquely viewed shape, a cross-sectional surface perpendicular to the X-direction and a cross-sectional surface perpendicular to the Y-direction.

As illustrated in FIG. 10, in this modification, the trench 10a is embedded by an embedding layer 18. A top surface 18a of the embedding layer 18 is flush with the top surface 12a of the mesa 12 and the top surface 14a of the laminated portion 14.

The embedding layer 18 is formed of an insulation material. Specifically, the embedding layer 18 may be formed of, for example, a synthetic resin material, such as a polyimide resin having insulation properties. The embedding layer 18 may be referred to as an insulation layer or a reinforcement layer.

The first extending portion 15b included in the electric resistance layer 15 and the second extending portion 16b included in the wiring layer 16 are provided at a position from the top surface 18a of the embedding layer 18 to the top surface 14a of the laminated portion 14.

Also in this modification, similarly to the first embodiment, the second extending portion 16b overlaps with the first extending portion 15b in the Z-direction, and the edge 16b3 of the second extending portion 16b (see FIG. 4) overlaps with the edge 15b3 of the first extending portion 15b (see FIG. 3) in the Z-direction. Furthermore, the wide width region 16b2 (connecting region) that overlaps with the wide width region 15b2, that is, a position that is included in the second extending portion 16b and that overlaps with the first extending portion 15b is electrically connected to the wiring 17. As a result, in a portion from the second region 16a to the wide width region 16b2 that is electrically connected to the wiring 17, the wiring layer 16 is not laid across the edge of the electric resistance layer 15. In this modification, it is also possible to obtain the same effect as that described above in the first embodiment.

Furthermore, in this modification, the embedding layer 18 that embeds the trench 10a is provided. With this configuration, for example, it is possible to further enhance protectiveness of the mesa 12, and it is also possible to enhance stiffness of the optical semiconductor device 10F. In addition, it is possible to support the first extending portion 15b and the second extending portion 16b by the embedding layer 18, so that an advantage is provided in that it is possible to suppress deformation or damage of each of the first extending portion 15b and the second extending portion 16b.

### Sixth Modification

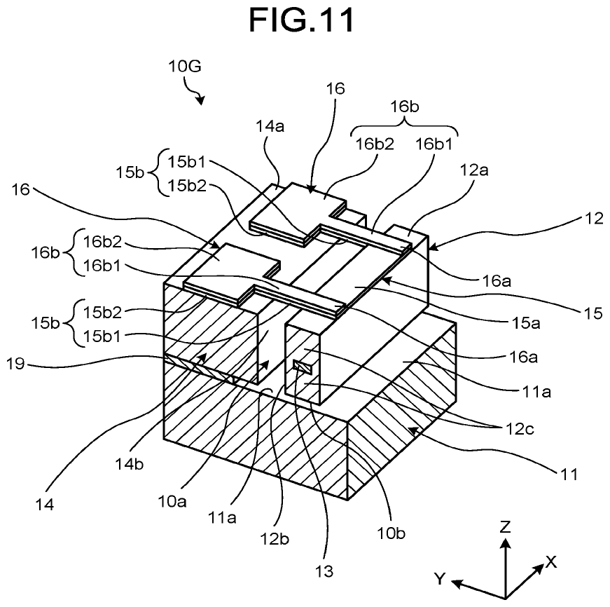

FIG. 11 is a perspective view of an optical semiconductor device 10G according to this modification including a part of a cross-sectional surface. FIG. 11 illustrates, together with an obliquely viewed shape, the cross-sectional surface perpendicular to the X-direction and a cross-sectional surface perpendicular to the Y-direction.

In this modification, an air gap 10b is provided at a position between the substrate 11 and the optical waveguide layer 13, for example, at a boundary portion located between the substrate 11 and the mesa 12. The air gap 10b acts as an air layer. The thermal conductivity of air is lower than that of the cladding layer 12c that is adjacent to the optical waveguide layer 13. The air gap 10b is an example of a high thermal resistance layer.

The air gap 10b is formed by performing etching. Specifically, for example, after the mesa 12 and the laminated portion 14 are formed on the substrate 11 by way of a sacrifice layer 19, etching is performed on the sacrifice layer 19. By performing etching, the sacrifice layer 19 disappears from the region exposed to the trench 10a. By stopping the etching process in a state in which the sacrifice layer 19 located between the substrate 11 and the mesa 12 disappears and the sacrifice layer 19 located between the substrate 11 and the laminated portion 14 remains, it is possible to obtain the configuration illustrated in FIG. 11. The sacrifice layer 19 may be formed by, for example, mixed crystal semiconductor material, such as InGaAs, InGaAsP, or AlInAs. Furthermore, the mesa 12 is not floating in the air, but a region of the mesa 12 that is not illustrated is supported by the substrate 11 via the sacrifice layer 19.

Also in this modification, similarly to the first embodiment described above, the second extending portion 16b overlaps with the first extending portion 15b in the Z-direction, and the edge 16b3 of the second extending portion 16b (see FIG. 4) overlaps with the edge 15b3 of the first extending portion 15b (see FIG. 3) in the Z-direction. Furthermore, the wide width region 16b2 (connecting region) that overlaps with the wide width region 15b2, that is, a position that is included in the second extending portion 16b and that overlaps with the first extending portion 15b is electrically connected to the wiring 17. As a result, in a portion from the second region 16a to the wide width region 16b2 that is electrically connected to the wiring 17, the wiring layer 16 is not laid across the edge of the electric resistance layer 15. In this modification, it is also possible to obtain the same effect as that described above in the first embodiment.

Furthermore, in this modification, the air gap 10b is provided as a high thermal resistance layer that has lower thermal conductivity than that of the cladding layer 12c (the region adjacent to the optical waveguide layer 13).

With this configuration, as compared to the case in which, for example, the air gap 10b is not provided, it is possible to suppress a decrease in heating efficiency caused by the electric resistance layer 15 as a result of the heat generated in the electric resistance layer 15 being delivered from the mesa 12 to the substrate 11.

### Seventh Modification

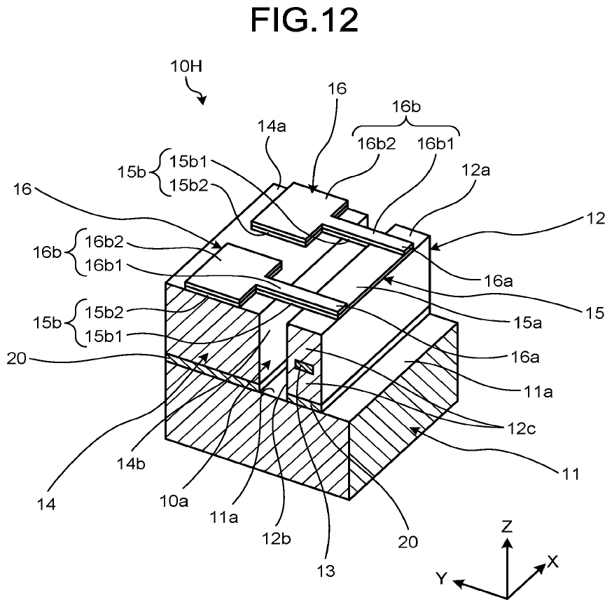

FIG. 12 is a perspective view of an optical semiconductor device 10H according to this modification including a part of a cross-sectional surface. FIG. 12 illustrates, together with an obliquely viewed shape, the cross-sectional surface perpendicular to the X-direction and the cross-sectional surface perpendicular to the Y-direction.

In this modification, a semiconductor layer 20 is provided at a position between the substrate 11 and the optical waveguide layer 13, for example, at a boundary portion between the substrate 11 and the mesa 12. The semiconductor layer 20 may be formed by a material, such as a mixed crystal semiconductor material made of, for example, InGaAs, InGaAsP, or AlInAs having lower thermal conductivity than that of the cladding layer 12c that is adjacent to the optical waveguide layer 13.

In this modification, the semiconductor layer 20 is provided as the high thermal resistance layer that has lower thermal conductivity than that of the cladding layer 12c (the region adjacent to the optical waveguide layer 13).

With this configuration, as compared to the case in which, for example, the semiconductor layer 20 is not provided, it is possible to suppress a decrease in heating efficiency caused by the electric resistance layer 15 as a result of the heat generated in the electric resistance layer 15 being delivered from the mesa 12 to the substrate 11.

Also in this modification, similar to the first embodiment, the second extending portion 16b overlaps with the first extending portion 15b in the Z-direction, and the edge 16b3 of the second extending portion 16b (see FIG. 4) overlaps with the edge 15b3 of the first extending portion 15b (see FIG. 3) in the Z-direction. Furthermore, the wide width region 16b2 (connecting region) that overlaps with the wide width region 15b2, that is, a position that is included in the second extending portion 16b and that overlaps with the first extending portion 15b is electrically connected to the wiring 17. As a result, in a portion from the second region 16a to the wide width region 16b2 that is electrically connected to the wiring 17, the wiring layer 16 is not laid across the edge of the electric resistance layer 15. In this modification, it is also possible to obtain the same effect as that described above in the first embodiment.

### Eighth Modification

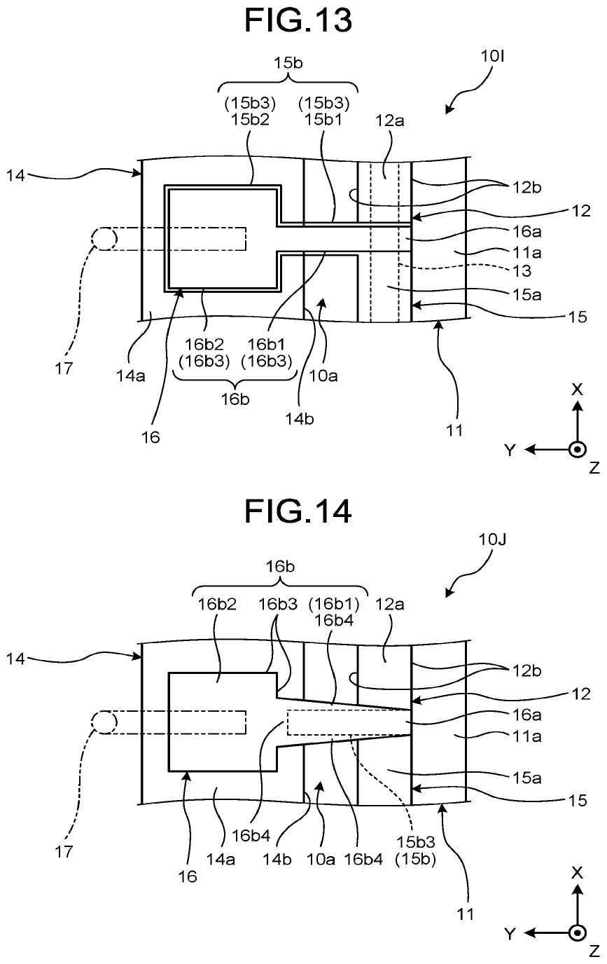

FIG. 13 is a plan view of an optical semiconductor device 10I according to this modification when viewed from a part of a position equivalent to that illustrated in FIG. 4. As illustrated in FIG. 13, in this modification, the first extending portion 15b in the electric resistance layer 15 projects farther than the edge 16b3 of the second extending portion 16b in the wiring layer 16 as a whole.

Also in this modification, in a portion from the second region 16a to the wide width region 16b2 that is electrically connected to the wiring 17, the wiring layer 16 is not laid across the edge of the electric resistance layer 15. As a result, in this modification, it is also possible to obtain the same effect as that described above in the first embodiment.

### Ninth Modification

FIG. 14 is a plan view of an optical semiconductor device 10J according to this modification when viewed from a part of a position equivalent to that illustrated in FIG. 4. As illustrated in FIG. 14, in this modification, the first extending portion 15b in the electric resistance layer 15 does not include the wide width region 15b2. The first extending portion 15b has a belt shape, and also has, as an example, a rectangular shape (square shape) and a plate shape.

In contrast, the wiring layer 16 has the same shape as that described in the third modification. In other words, the width of the narrow width region 16b1 is gradually increased as the narrow width region 16b1 is away from the mesa 12, the first region 15a, and the second region 16a.

The narrow width region 16b1 overlaps with the first extending portion 15b. Furthermore, the width of the narrow width region 16b1 is equal to or larger than the width of the first extending portion 15b (the same or wider width). The narrow width region 16b1 is an example of a third region.

Furthermore, the second extending portion 16b includes a projecting region 16b4 that projects farther than the edge 15b3 of the first extending portion 15b in the outer side of the width direction (the outer side of the X-direction) and in the outer side of the extending direction (the outer side of the Y-direction). The wide width region 16b2 is a part of the projecting region 16b4. Furthermore, the wide width region 16b2 (connecting region) that is electrically connected to the wiring 17 is away from the second region 16a.

With this configuration, the length of the edge 15b3 of the first extending portion 15b that is covered by the narrow width region 16b1 (the second extending portion 16b) is further increased. In this case, even if a burr is produced in the edge 15b3, it is possible to further increase the cross-sectional area of a portion that covers the burr in the narrow width region 16b1, so that it is possible to decrease the electric resistance of the second extending portion 16b, and, in addition, it is possible to more efficiently supply electrical power to the electric resistance layer 15 via the wiring 17 and the wiring layer 16.

### Tenth Modification

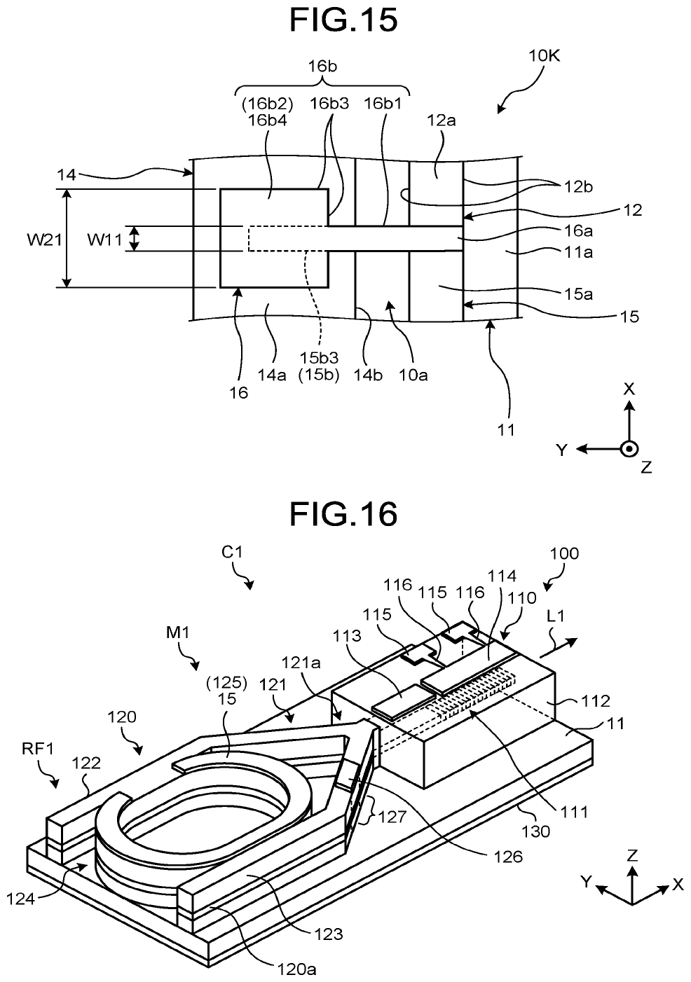

FIG. 15 is a plan view of an optical semiconductor device 10K according to this modification when viewed from a part of a position equivalent to that illustrated in FIG. 4. As illustrated in FIG. 15, in this modification, the first extending portion 15b included in the electric resistance layer 15 does not include the wide width region 15b2 (see FIG. 3) described in the first embodiment. The first extending portion 15b has a belt shape, and also has, as an example, a rectangular shape (square shape) and a plate shape.

In contrast, the wiring layer 16 includes the narrow width region 16b1 and the wide width region 16b2 that are the same as those described above in the first embodiment.

Furthermore, the first extending portion 15b extends to a position that overlaps with the wide width region 16b2 included in the wiring layer 16.

Therefore, the wide width region 16b2 overlaps with the first extending portion 15b. In addition, a width W21 of the wide width region 16b2 is larger than a width W11 of the first extending portion 15b. The wide width region 16b2 is an example of the third region.

Furthermore, the wide width region 16b2 includes the projecting region 16b4 that projects farther than the edge 15b3 of the first extending portion 15b in the outer side of the width direction (the outer side of the X-direction) and in the outer side of the extending direction (the outer side of the Y-direction).

With this configuration, the length of the edge 15b3 of the first extending portion 15b that is covered by the wide width region 16b2 (the second extending portion 16b) is further increased. In this case, even if a burr is produced in the edge 15b3, it is possible to further increase the cross-sectional area of a portion that covers the burr in the wide width region 16b2, so that it is possible to decrease the electric resistance of the second extending portion 16b, and, in addition, it is possible to more efficiently supply electrical power to the electric resistance layer 15 via the wiring 17 and the wiring layer 16.

### Second Embodiment

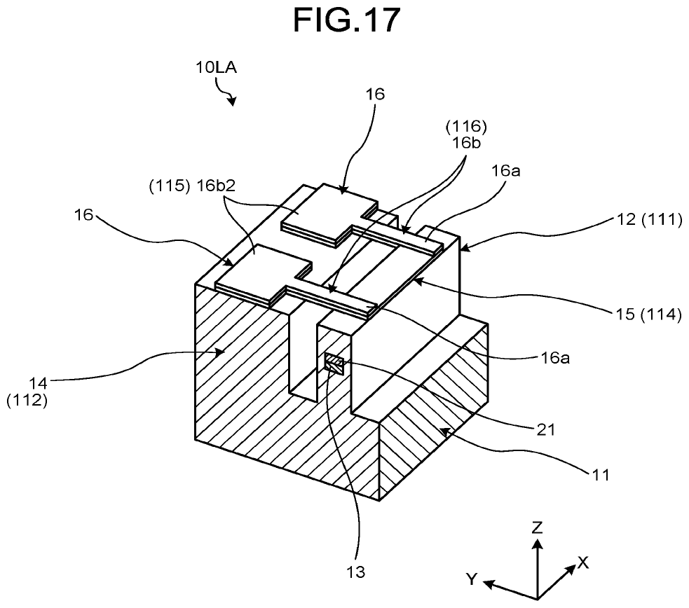

FIG. 16 is a perspective view of an integrated semiconductor laser device 100 according to a second embodiment. As illustrated in FIG. 16, the integrated semiconductor laser device 100 includes a first optical waveguide portion 110 and a second optical waveguide portion 120 that are formed on the common substrate 11. The integrated semiconductor laser device 100 is configured to oscillate laser and output a laser beam Ll. The substrate 11 is formed of, for example, an n-type InP. Furthermore, an n-side electrode 130 is formed on the back surface of the substrate 11. The n-side electrode 130 is constituted by including, for example, AuGeNi, and forms an ohmic contact with the substrate 11.

The first optical waveguide portion 110 includes an optical waveguide 111, a laminated portion 112, a p-side electrode 113, a micro heater 114 that is made of Ti, two electrode pads 115, and conductor wiring 116 that has a tapered shape. The first optical waveguide portion 110 has an embedding structure. The optical waveguide 111 is formed so as to be drawn into the laminated portion 112 in the X-direction. The laminated portion 112 has a function of a cladding portion with respect to the optical waveguide 111.

The p-side electrode 113 is arranged, on the laminated portion 112, to as to be along a predetermined portion (a gain portion) of the optical waveguide 111. Furthermore, a SiN protection film that will be described later is formed on the laminated portion 112, and the p-side electrode 113 is brought into contact with the laminated portion 112 via an opening portion that is formed on the SiN protection film. The micro heater 114 is arranged, on the SiN protection film of the laminated portion 112, so as to be along a predetermined portion of the optical waveguide 111. Each of the electrode pads 115 is arranged on the SiN protection film of the laminated portion 112 and is electrically connected to the micro heater 114 via the conductor wiring 116. The micro heater 114 generates heat as a result of an electric current being supplied from each of the electrode pads 115 via the conductor wiring 116.

The second optical waveguide portion 120 includes a two-branching unit 121, two arm portions 122 and 123, a ring shaped waveguide (ring resonator) 124, and a micro heater 125 that is made of NiCr or the like.

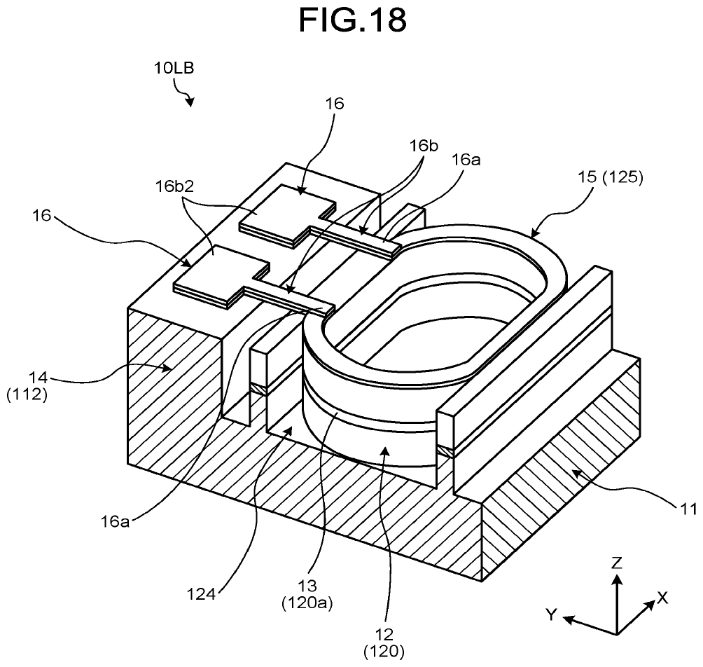

The two-branching unit 121 is constituted by a 1×2 branch type waveguide that includes a 1×2 type multimode interference (MMI) waveguide 121a, and the two port sides are connected to the two arm portions 122 and 123, respectively, whereas the one port side is connected to the first optical waveguide portion 110 side. By using the two-branching unit 121, one of the two ends of the respective two arm portions 122 and 123 is integrated and is optically coupled to a diffraction grating layer 21 (illustrated in FIG. 17). The diffraction grating layer 21 constitutes a DBR structure.

Both of the arm portions 122 and 123 are drawn in the X-direction and are arranged to sandwich the ring shaped waveguide 124. Both of the arm portions 122 and 123 are arranged close to the ring shaped waveguide 124 and are optically coupled to the ring shaped waveguide 124 at a same coupling coefficient K. The value of K is, for example, 0.2. The arm portions 122 and 123 and the ring shaped waveguide 124 constitute a ring resonator filter RF1. Furthermore, the ring resonator filter RF1 and the two-branching unit 121 constitute a reflective mirror Ml. The micro heater 125 has a ring shape and is arranged on the SiN protection film that is formed to cover the ring shaped waveguide 124. The micro heater 125 generates heat as a result of an electric current being supplied, and heats the ring shaped waveguide 124. By changing an amount of the supplied electric current, temperature of the ring shaped waveguide 124 is changed and the refractive index thereof is accordingly changed.

Each of the two-branching unit 121, the arm portions 122 and 123, and the ring shaped waveguide 124 has a high mesa structure in which an optical waveguide layer 120a made of GaInAsP is sandwiched by a lower part cladding layer and an upper part cladding layer.

Furthermore, a micro heater 126 is arranged on a part of the SiN protection film of the arm portion 123. An area below the micro heater 126 included in the arm portion 123 functions as a phase adjustment unit 127 that changes the phase of light. The micro heater 126 generates heat as a result of an electric current being supplied, and heats the phase adjustment unit 127. By changing an amount of the supplied electric current, temperature of the phase adjustment unit 127 is changed and the refractive index is accordingly changed.

Each of the first optical waveguide portion 110 and the second optical waveguide portion 120 constitutes an optical resonator Cl that is constituted by the diffraction grating layer 21 and a reflective mirror Ml that are a pair of wavelength selection elements and that are optically connected with each other.

The integrated semiconductor laser device 100 has a distributed Bragg reflector (DBR) structure exhibiting periodic wavelength characteristics and a ring resonator, and is operated as a vernier type wavelength-tunable laser by performing control of the wavelength characteristics by an amount of heat generation of the heater. A schematic view of a heater purpose conductor wiring structure having the optical waveguide layer included in these is illustrated in FIG. 17 and FIG. 18.

FIG. 17 is a perspective view illustrating a configuration example in which the optical semiconductor device 10A according to the first embodiment is applied to the DBR structure. As illustrated in FIG. 17, an optical semiconductor device 10LA has the same configuration as that of the optical semiconductor device 10A according to the first embodiment except that the optical semiconductor device 10LA includes, in the mesa 12, the diffraction grating layer 21 on the opposite side to the substrate 11 that is adjacent to the optical waveguide layer 13. The optical waveguide 111 corresponds to the mesa 12 that includes the optical waveguide layer 13, the laminated portion 112 corresponds to the laminated portion 14, the micro heater 114 corresponds to the electric resistance layer 15, the electrode pads 115 correspond to the wide width regions 16b2 (connecting region) included in the wiring layer 16, and the conductor wiring 116 corresponds to the second extending portion 16b included in the wiring layer 16.

FIG. 18 is a perspective view illustrating a configuration example in which the optical semiconductor device 10B according to the first modification is applied to the ring resonator. As illustrated in FIG. 18, an optical semiconductor device 10LB includes the ring shaped waveguide 124 that has a ring resonator structure and that has the same configuration as that of the optical semiconductor device 10B having a high mesa structure described in the first modification. The optical semiconductor device 10LB has the same configuration as that of the optical semiconductor device 10B according to the first modification except that each of the mesa 12, the first region 15a of the electric resistance layer 15, and the second region 16a of the wiring layer 16 has a ring shape. The optical waveguide layer 120a corresponds to the optical waveguide layer 13, the second optical waveguide portion 120 corresponds to the mesa 12 that includes the optical waveguide layer 13, and the micro heater 125 corresponds to the electric resistance layer 15.

With the integrated semiconductor laser device 100 according to the second embodiment, the integrated semiconductor laser device 100 has the same configuration as that of the optical semiconductor device 10A according to the first embodiment and the optical semiconductor device 10B according to the first modification, so that it is possible to obtain the same effect as that obtained by the optical semiconductor devices 10A and 10B.

As described above, the structure according to the present disclosure is able to be applied to not only a semiconductor optical waveguide but also the integrated semiconductor laser device 100 that includes the DBR illustrated in FIG. 17 or the ring resonator illustrated in FIG. 18.

According to the present disclosure, it is possible to form a wiring layer with higher accuracy in an optical semiconductor device that includes an electric resistance layer and a wiring layer on, for example, a mesa.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical semiconductor device comprising:
a base including a base surface;
a mesa protruding from the base surface in a first direction intersecting the base surface and extending along the base surface;
an optical waveguide layer provided inside the mesa or provided inside the base so as to have a region at least overlapping with the mesa in the first direction;
an electric resistance layer including
a first region provided on the mesa, and
a first extending portion extending from the first region in a direction intersecting an extending direction of the mesa; and
a wiring layer including
a second region electrically connected to the electric resistance layer and configured to partially cover the first region, and
a second extending portion configured to at least partially cover the first extending portion, the second extending portion extending from the second region in a direction intersecting the extending direction of the mesa, wherein
a connecting region electrically connected to wiring is provided at a position included in the second extending portion, the position overlapping with the first extending portion.

2. The optical semiconductor device according to claim 1, wherein a first edge of the first extending portion and a second edge of the second extending portion overlap with each other.

3. The optical semiconductor device according to claim 2, wherein the first extending portion is configured to at least partially project in an outer side of the second edge of the second extending portion.

4. An optical semiconductor device comprising:
a base including a base surface;
a mesa protruding from the base surface in a first direction intersecting the base surface and extending along the base surface;
an optical waveguide layer provided inside the mesa or provided inside the base so as to have a region at least overlapping with the mesa in the first direction;
an electric resistance layer including
a first region provided on the mesa, and
a first extending portion extending from the first region in a direction intersecting an extending direction of the mesa; and
a wiring layer including
a second region electrically connected to the electric resistance layer and configured to partially cover the first region, and
a second extending portion configured to at least partially cover the first extending portion, the second extending portion extending from the second region in a direction intersecting the extending direction of the mesa, wherein
the second extending portion includes
a third region having a width larger than a width of the first extending portion, the third region overlapping with the first extending portion, and
a connecting region electrically connected to wiring at a position away from the second region.

5. The optical semiconductor device according to claim 4, wherein the second extending portion includes a projecting region projecting in an outer side of a first edge of the first extending portion in a width direction of the second extending portion and projecting in an outer side of the second extending portion in the extending direction.

6. The optical semiconductor device according to claim 1, wherein electric resistivity of the electric resistance layer is larger than electric resistivity of the wiring layer.

7. The optical semiconductor device according to claim 1, further comprising:
a trench provided so as to be adjacent to the mesa; and
an embedding layer configured to embed the trench.

8. The optical semiconductor device according to claim 1, further comprising a high thermal resistance layer having thermal conductivity lower than thermal conductivity exhibited in a region adjacent to the optical waveguide layer.

9. The optical semiconductor device according to claim 8, wherein the high thermal resistance layer is an air gap.

10. The optical semiconductor device according to claim 8, wherein the high thermal resistance layer is formed of a semiconductor material.

11. An integrated semiconductor laser device comprising the optical semiconductor device according to claim 1.
